(19) United States
(12) Patent Application Publication
(10) Pub. No.: US 2023/0384668 A1
(43) Pub. Date: Nov. 30, 2023

(54) PHOTORESIST COMPOSITION AND METHOD FOR MANUFACTURING A SEMICONDUCTOR DEVICE

(71) Applicant: TAIWAN SEMICONDUCTOR MANUFACTURING COMPANY, LTD., Hsinchu (TW)

(72) Inventors: An-Ren ZI, Hsinchu City (TW); Ching-Yu CHANG, Yuansun Village (TW)

(21) Appl. No.: 18/232,264

(22) Filed: Aug. 9, 2023

Related U.S. Application Data
(62) Division of application No. 17/246,496, filed on Apr. 30, 2021.

(51) Int. Cl. G03F 7/004; G03F 7/20; G03F 7/38; G03F 7/40; G03F 7/00

(52) U.S. Cl. CPC G03F 7/0042; G03F 7/0041; G03F 7/0045; G03F 7/0048; G03F 7/2004; G03F 7/38; G03F 7/40; G03F 7/70033

(57) ABSTRACT

A method for manufacturing a semiconductor device includes forming a resist layer including a resist composition over a substrate. The resist composition includes: a metal, a ligand, and a solvent. The solvent is mixture of a first solvent having a vapor pressure of at least 0.75 kPa, wherein the first solvent is one or more of an ether, an ester, an alkane, an aldehyde, or a ketone, and a second solvent different from the first solvent. Alternatively, the solvent is a third solvent, wherein the third solvent is a C4-C14 tertiary alcohol. The resist layer is patterned.

### RELATED APPLICATION

This application is a divisional application of U.S. application Ser. No. 17/246,496, filed Apr. 30, 2021, the entire disclosure of which is incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

As the semiconductor industry has progressed into nanometer technology process nodes in pursuit of higher device density, higher performance, and lower costs, there have been challenges in reducing semiconductor feature size. Extreme ultraviolet lithography (EUVL) has been developed to form smaller semiconductor device feature size and increase device density on a semiconductor wafer. In order to improve EUVL an increase in wafer exposure throughput is desirable.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show a process stage of a sequential operation according to an embodiment of the disclosure.

FIG. 4 shows a process stage of a sequential operation according to an embodiment of the disclosure.

FIGS. 5A and 5B show a process stage of a sequential operation according to an embodiment of the disclosure.

FIGS. 6A and 6B show a process stage of a sequential operation according to an embodiment of the disclosure.

FIG. 7A shows organometallic precursors according to embodiments of the disclosure.

FIG. 7B shows a reaction the organometallic precursors undergo when exposed to actinic radiation. FIG. 7C shows examples of organometallic precursors according to embodiments of the disclosure.

FIG. 8 shows examples of resist solvents according to embodiments of the disclosure.

FIGS. 9A and 9B show examples of resist dispensing and baking according to embodiments of the disclosure.

FIG. 10 shows a process stage of a sequential operation according to an embodiment of the disclosure.

FIGS. 11A and 11B show a process stage of a sequential operation according to an embodiment of the disclosure.

FIG. 12 shows a process stage of a sequential operation according to an embodiment of the disclosure.

FIGS. 13A and 13B show a process stage of a sequential operation according to an embodiment of the disclosure.

FIGS. 14A and 14B show a process stage of a sequential operation according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

To improve EUVL an increase in wafer exposure throughput is desirable. Wafer exposure throughput can be increased by reducing the required exposure dose to expose the photoresist. Increasing the photon absorption of the photoresist allows the exposure to be reduced. However, elements found in organic photoresists, such as C, N, O are weak EUV absorbers. Metals used in metallic resists have increased absorbance of EUV radiation. However, metallic resists suffer from certain defects in a greater degree than conventional chemically amplified resists. Embodiments of the present disclosure provide novel resist compositions and semiconductor device manufacturing techniques to reduce defects associated with metallic resists. In some embodiments, a novel solvent for the resist composition is used to reduce defects.

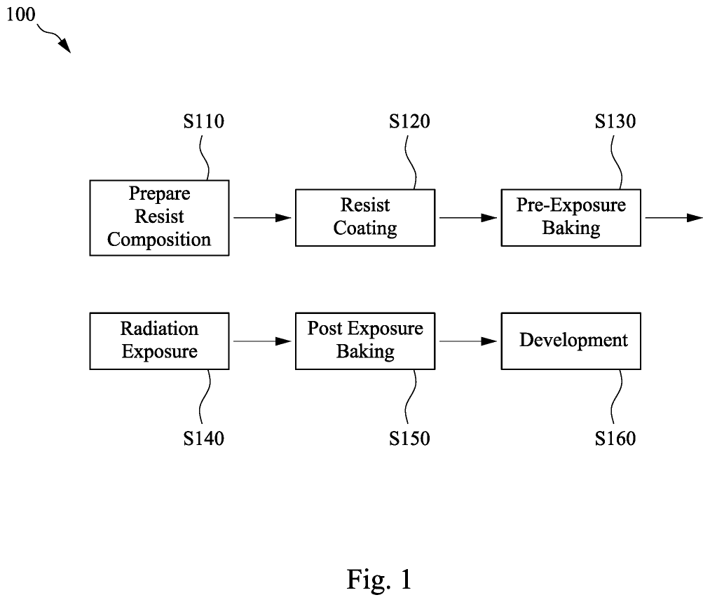

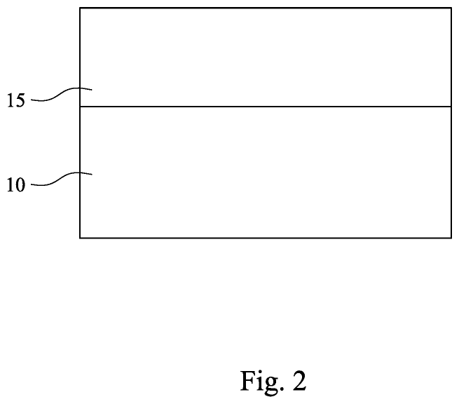

FIG. 1 illustrates a process flow 100 for manufacturing a semiconductor device according to embodiments of the disclosure. A resist composition is prepared in operation S110. In some embodiments, metal particles and ligands are mixed together in a solvent. In some embodiments, an organometallic compound or precursor is mixed in a solvent to form the resist composition. In some embodiments, the resist composition is a photoresist composition. When exposed to actinic radiation, photoresist compositions undergo one or more chemical reactions causing a change in solubility in a developer composition. The resist composition is subsequently coated on a surface of a layer to be patterned (or target layer) or a substrate 10 in operation S120, in some embodiments, to form a photoresist layer 15, as shown in FIG. 2. Then the photoresist layer 15 undergoes a first baking operation (or pre-exposure baking) S130 to evaporate solvents in the photoresist composition in some embodiments. The photoresist layer is baked at a temperature and time sufficient to dry or cure the photoresist layer 15. In some embodiments, the photoresist layer is heated at a temperature of ranging from about 40° C. to about 300° C. for about 10 seconds to about 10 minutes. In some embodiments, the photoresist layer is heated at a temperature of ranging from about 80° C. to about 250° C., in other embodiments, the photoresist layer is heated at a temperature of ranging from about 100° C. to about 200° C. Heating the photoresist layer 15 at temperature below the disclosed ranges or for a shorter period of time than the disclosed range, may result in insufficient drying or curing of the photoresist layer. Heating the photoresist layer 15 at temperature above the disclosed ranges or for a longer period of time than the disclosed range, may result in damage to the photoresist layer or underlying layers.

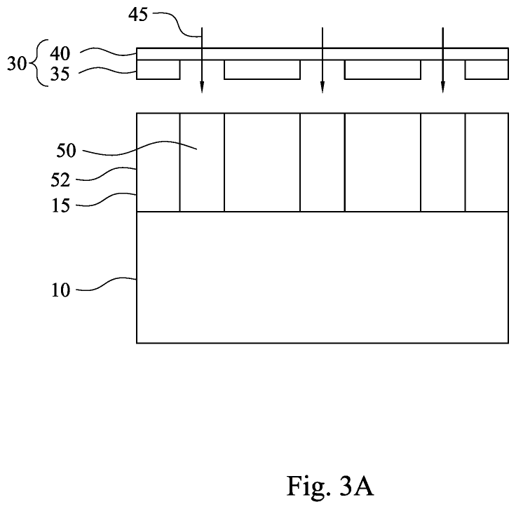

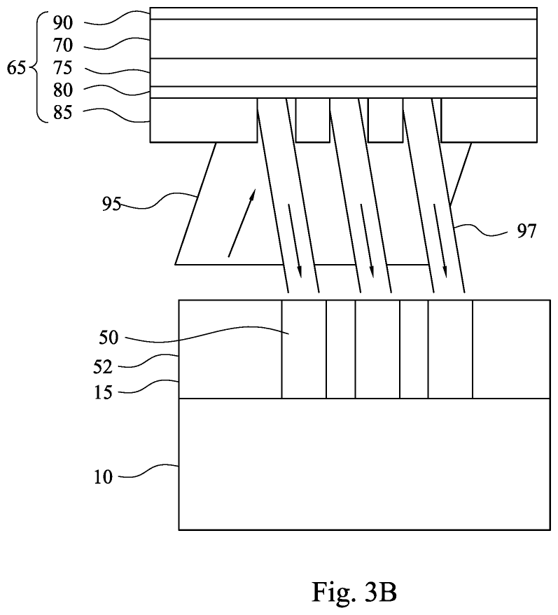

After the first baking operation S130, the photoresist layer 15 is selectively exposed to actinic radiation 45/97 (see FIGS. 3A and 3B) in operation S140. In some embodiments, the photoresist layer 15 is selectively exposed to ultraviolet radiation. In some embodiments, the ultraviolet radiation is deep ultraviolet radiation (DUV). In some embodiments, the ultraviolet radiation is extreme ultraviolet (EUV) radiation. In some embodiments, the radiation is an electron beam.

As shown in FIG. 3A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation a reflective photomask 65 is used to form the patterned exposure light, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist-coated substrate 10, while the portion of the extreme ultraviolet radiation incident upon the absorber layer 85 is absorbed by the photomask. In some embodiments, additional optics, including mirrors, are between the reflective photomask 65 and the photoresist-coated substrate.

The region 50 of the photoresist layer exposed to radiation undergoes a chemical reaction thereby changing its solubility in a subsequently applied developer relative to the region 52 of the photoresist layer not exposed to radiation. In some embodiments, the portion 50 of the photoresist layer exposed to radiation undergoes a reaction making the exposed portion more soluble in a developer. In other embodiments, the portion 50 of the photoresist layer exposed to radiation undergoes a crosslinking reaction making the exposed portion 50 less soluble in a developer.

Next, the photoresist layer 15 undergoes a post-exposure bake in operation S150. In some embodiments, the photoresist layer 15 is heated to a temperature of about 50° C. to 160° C. for about 20 seconds to about 10 minutes. In some embodiments, the photoresist layer 15 is heated for about 30 seconds to about 5 minutes. In some embodiments, the photoresist layer 15 is heated for about 1 minute to about 2 minutes. The post-exposure baking may be used to assist in the generating, dispersing, and reacting of ions or free radicals generated from the impingement of the radiation 45/97 upon the photoresist layer 15 during the exposure. Such assistance helps to create or enhance chemical reactions that generate chemical differences between the exposed region 50 and the unexposed region 52 within the photoresist layer. These chemical differences also cause differences in the solubility between the exposed region 50 and the unexposed region 52.

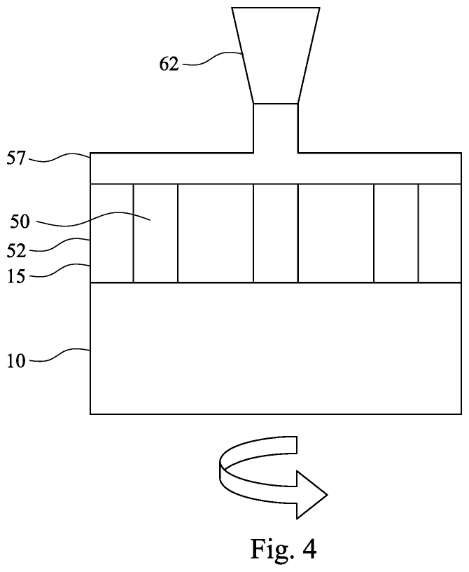

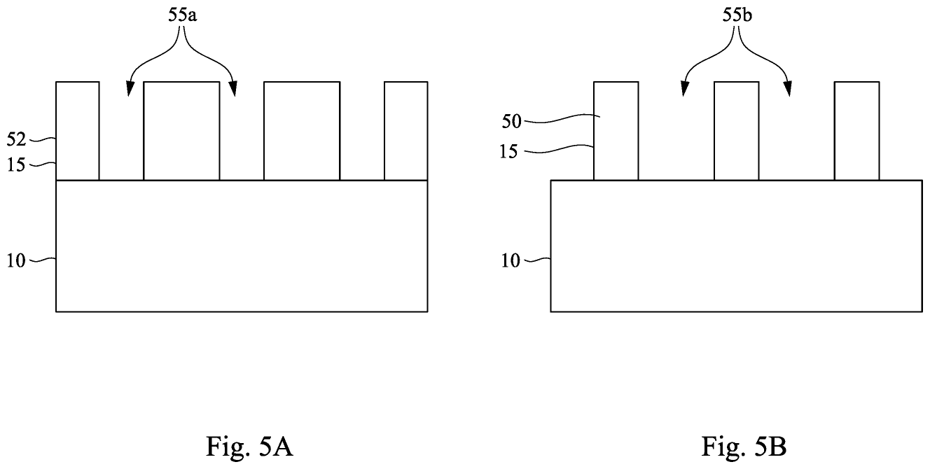

The selectively exposed photoresist layer is subsequently developed by applying a developer to the selectively exposed photoresist layer in operation S160. As shown in FIG. 4, a developer 57 is supplied from a dispenser 62 to the photoresist layer 15. In some embodiments, the exposed portion 50 of the photoresist layer is removed by the developer 57 forming a pattern of openings 55a in the photoresist layer 15 to expose the substrate 10, as shown in FIG. 5A. In other embodiments, the unexposed portion of the photoresist layer 52 is removed by the developer 57 forming a pattern of openings 55b in the photoresist layer 15 to expose the substrate 20, as shown in FIG. 5B.

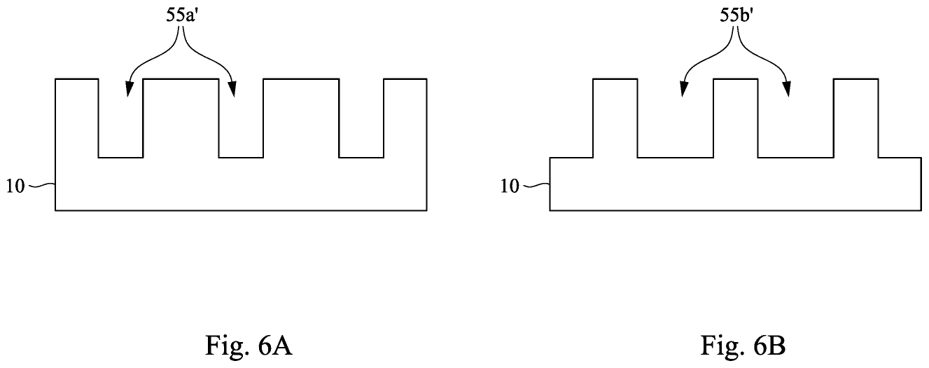

In some embodiments, the pattern of openings 55a, 55b in the photoresist layer 15 are extended into the layer to be patterned or substrate 10 to create a pattern of openings 55a′, 55b′ in the substrate 10, thereby transferring the pattern in the photoresist layer 15 into the substrate 10, as shown in FIGS. 6A and 6B. The pattern is extended into the substrate by etching, using one or more suitable etchants. The remaining photoresist of the photoresist pattern 50, 52 is at least partially removed during the etching operation in some embodiments. In other embodiments, the remaining photoresist of the photoresist pattern 50, 52 is removed after etching the substrate 10 by using a suitable photoresist stripper solvent or by a photoresist ashing operation.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric material having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are either positive tone resists or negative tone resists. A positive tone resist refers to a photoresist material that when exposed to radiation, such as UV light, becomes soluble in a developer, while the region of the photoresist that is non-exposed (or exposed less) is insoluble in the developer (see FIG. 5A). A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation (see FIG. 5B).

Whether a resist is a positive tone or negative tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent, such as n-butyl acetate (nBA). Further, in some negative tone photoresists developed with the TMAH solution, the unexposed regions of the photoresist are removed by the TMAH, and the exposed regions of the photoresist, that undergo cross-linking upon exposure to actinic radiation, remain on the substrate after development.

In some embodiments, such as when EUV radiation is used, the photoresist compositions according to the present disclosure are metallic resists (or metal-containing resists). The metal-containing resists include metallic cores complexed with one or more ligands in a solvent. In some embodiments, the resist includes metal particles. In some embodiments, the metal particles are nanoparticles. As used herein, nanoparticles are particles having an average particle size between about 1 nm and about 20 nm. In some embodiments, the metallic cores, including from 1 to about 18 metal particles, are complexed with one or more organic ligands in a solvent. In some embodiments, the metallic cores include 3, 6, 9, or more metal nanoparticles complexed with one or more organic ligands in a solvent.

In some embodiments, the metal particle is one or more of titanium (Ti), zinc (Zn), zirconium (Zr), nickel (Ni), cobalt (Co), manganese (Mn), copper (Cu), iron (Fe), strontium (Sr), tungsten (W), vanadium (V), chromium (Cr), tin (Sn), hafnium (Hf), indium (In), cadmium (Cd), molybdenum (Mo), tantalum (Ta), niobium (Nb), aluminum (Al), cesium (Cs), barium (Ba), lanthanum (La), cerium (Ce), silver (Ag), antimony (Sb), combinations thereof, or oxides thereof. In some embodiments, the metal particles include one or more selected from the group consisting of Ce, Ba, La, Ce, In, Sn, Ag, Sb, and oxides thereof.

In some embodiments, the metal nanoparticles have an average particle size between about 2 nm and about 5 nm. In some embodiments, the amount of metal nanoparticles in the resist composition ranges from about 0.5 wt. % to about 15 wt. % based on the weight of the nanoparticles and the solvent. In some embodiments, the amount of nanoparticles in the resist composition ranges from about 5 wt. % to about 10 wt. % based on the weight of the nanoparticles and the solvent. Below about 0.5 wt. % metal nanoparticles, the resist coating is too thin. Above about 15 wt. % metal nanoparticles, the resist coating is too thick and viscous.

In some embodiments, the metallic core is complexed by a thermally stable ligand, wherein the thermally stable ligand includes branched or unbranched, cyclic or non-cyclic, saturated organic groups, including C1-C7 alkyl groups or C1-C7 fluoroalkyl groups. The C1-C7 alkyl groups or C1-C7 fluoroalkyl groups include one or more substituents selected from the group consisting of —CF₃, —SH, —OH, ═O, —S—, —P—, —PO₂, —C(═O)SH, —C(═O)OH, —C(═O)O—, —O—, —N—, —C(═O)NH, —SO₂OH, —SO₂SH, —SOH, and —SO₂—. In some embodiments, the ligand includes one or more substituents selected from the group consisting of —CF₃, —OH, —SH, and —C(═O)OH substituents.

In some embodiments, the ligand is a carboxylic acid or sulfonic acid ligand. For example, in some embodiments, the ligand is a methacrylic acid. In some embodiments, the metal particles are nanoparticles, and the metal nanoparticles are complexed with ligands including aliphatic or aromatic groups. The aliphatic or aromatic groups may be unbranched or branched with cyclic or noncyclic saturated pendant groups containing 1-9 carbons, including alkyl groups, alkenyl groups, and phenyl groups. The branched groups may be further substituted with oxygen or halogen. In some embodiments, each metal particle is complexed by 1 to 25 ligand units. In some embodiments, each metal particle is complexed by 3 to 18 ligand units.

In some embodiments, the resist composition includes about 0.1 wt. % to about 20 wt. % of the ligands based on the total weight of the resist composition. In some embodiments, the resist includes about 1 wt. % to about 10 wt. % of the ligands. In some embodiments, the ligand concentration is about 10 wt. % to about 40 wt. % based on the weight of the metal particles and the weight of the ligands. Below about 10 wt. % ligand, the organometallic photoresist does not function well. Above about 40 wt. % ligand, it is difficult to form a consistent photoresist layer.

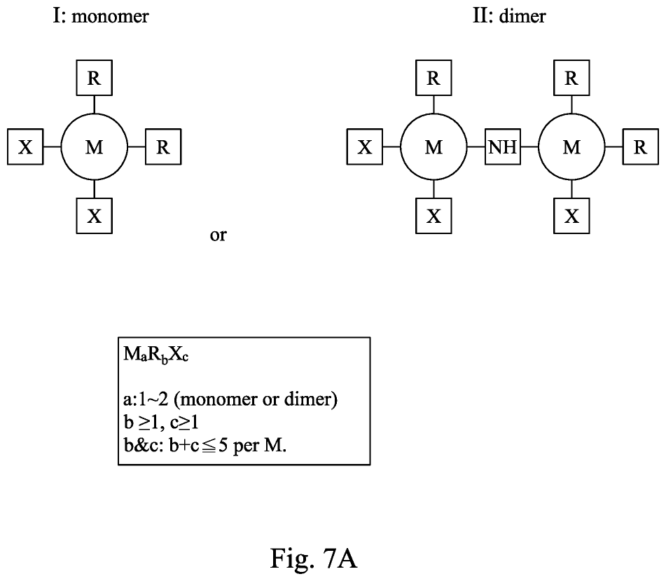

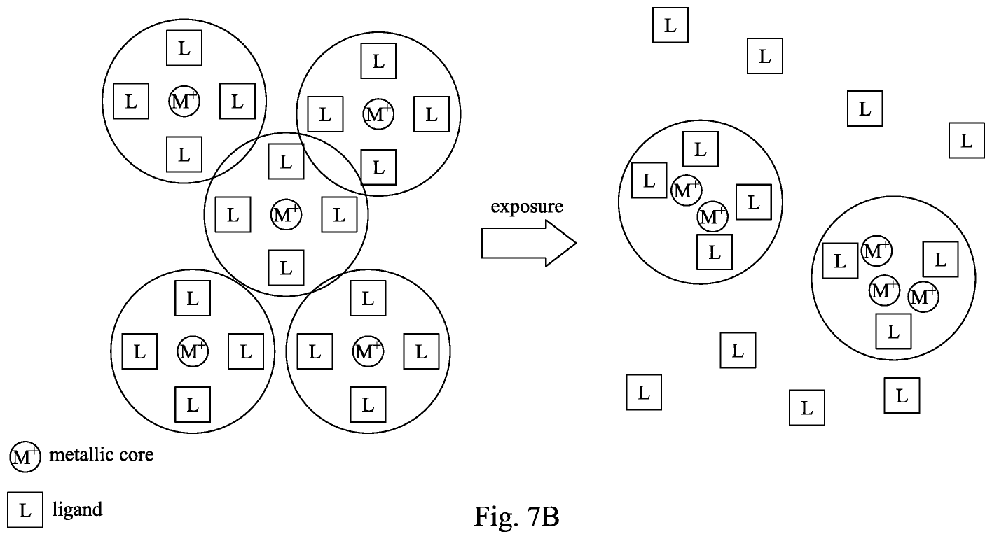

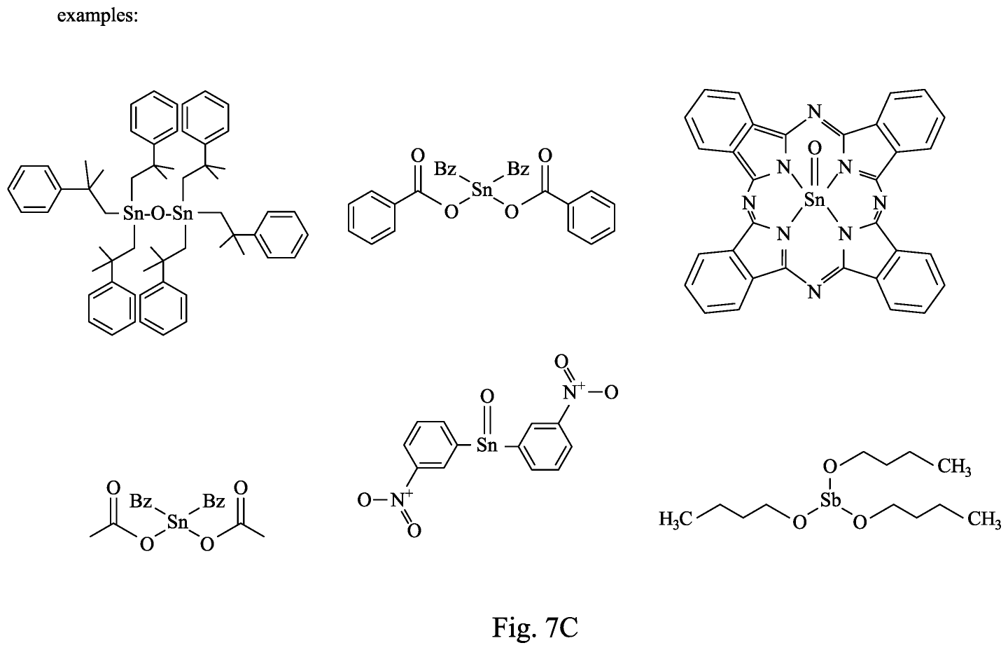

In some embodiments, the photoresist layer 15 is made of a metallic photoresist composition, including a first compound or a first precursor and a second compound or a second precursor. The first precursor or first compound is an organometallic having a formula: MₐR_{b}X_{c}, as shown in FIG. 7A, where M is at least one of Sn, Bi, Sb, In, Te, Ti, Zr, Hf, V, Co, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, Bi, Sb, In, Te, and combinations thereof. In some embodiments, R is a C3-C6 alkyl, alkenyl, or carboxylate. In some embodiments, R is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. X is a ligand, ion, or other moiety, which is reactive with the second compound or second precursor; and 1≤a≤2, b≥1, c≥1, and b+c≤5 in some embodiments. In some embodiments, the alkyl, alkenyl, or carboxylate group is substituted with one or more fluoro groups. In some embodiments, the organometallic precursor is a dimer, as shown in FIG. 7A, where each monomer unit is linked by an amine group. Each monomer has a formula: MₐR_{b}X_{c}, as defined above.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

In some embodiments, R is alkyl, such as CₙH₂ₙ₊₁ where n≥3. In some embodiments, R is fluorinated, e.g., having the formula CₙFₓH₍₍₂ₙ₊₁₎₋ₓ₎. In some embodiments, R has at least one beta-hydrogen or beta-fluorine. In some embodiments, R is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core M⁺ with ligands L attached to the metallic core M⁺, as shown in FIG. 7B. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl tris(dimethylamino) tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl tris(dimethylamino) tin, or n-propyl tris(butoxy) tin. In some embodiments, the organometallic precursors or organometallic compounds are fluorinated.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently a halogen selected from the group consisting of F, Cl, Br, and I.

FIG. 7B shows organometallic precursors undergoing a reaction as a result of exposure to actinic radiation in some embodiments. As a result of exposure to the actinic radiation, ligand groups L are split off from the metallic core M⁺ of the metallic precursors, and two or more metallic precursor cores bond with each other.

FIG. 7C shows examples of organometallic precursors according to embodiments of the disclosure. In FIG. 7C, Bz is a benzene group.

In some embodiments, the resist layer 15 is formed by mixing the organometallic compound in a solvent to form a resist composition and dispensing the resist composition onto the substrate 10. To aid in the mixing and dispensing of the photoresist, the solvent is chosen at least in part based upon the materials chosen for the metallic resist. In some embodiments, the solvent is chosen such that the organometallic is evenly dissolved into the solvent and dispensed upon the layer to be patterned.

In some embodiments, the solvent for the resist composition is a mixture of a first solvent having a vapor pressure of at least 0.75 kPa and a second solvent. The first solvent is one or more of an ether, an ester, an alkane, an aldehyde, or a ketone in some embodiments. The second solvent is different from the first solvent. In some embodiments, the second solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, 2-heptanone, and combinations thereof.

In some embodiments, the first solvent is a C2-C14 compound. In some embodiments, the first solvent does not include alcohol groups (—OH groups), carboxyl groups (—COOH groups), amine groups (—NH₂, —NHR, —NR₂), or amide groups (—CONH₂, —CONHR, —CONR₂). In some embodiments, a boiling point of the first solvent ranges from greater than 25° C. to less than 300° C. In some embodiments, the first solvent has a melting point of less than 23° C.

In some embodiments, the first solvent includes an ester, and the ester is selected from the group consisting of a methyl acetate, an ethyl acetate, a propyl acetate, an isopropyl acetate, an n-butyl acetate, an isobutyl acetate, a sec-butyl acetate, a tert-butyl acetate, and combinations thereof. In some embodiments, the ester includes substituents. In some embodiments, the substituents include one or more halogens, such as F, Cl, Br, or I.

In some embodiments, the first solvent is an ether, and the ether is selected from the group consisting of a diethyl ether, a dipropyl ether, an ethyl propyl ether, a butyl propyl ether, a tert-amyl methyl ether, and combinations thereof. In some embodiments, the ether includes substituents. In some embodiments, the substituents include one or more halogens, such as F, Cl, Br, or I.

In some embodiments, the first solvent is a ketone, and the ketone is selected from the group consisting of a dimethyl ketone, a methyl ethyl ketone, a diethyl ketone, a methyl propyl ketone, an ethyl propyl ketone, and combinations thereof. In some embodiments, the ketone includes substituents. In some embodiments, the substituents include one or more halogens, such as F, Cl, Br, or I.

In some embodiments, the first solvent is an aldehyde, and the aldehyde is selected from the group consisting of a propanal, a butanal, a pentanal, a hexanal, a 3-methylbutanal, a 2-methylbutanal, a 2-methylpentanal, a 2 ethylpentanal, and combinations thereof. In some embodiments, the aldehyde includes substituents. In some embodiments, the substituents include one or more halogens, such as F, Cl, Br, or I.

In some embodiments, the first solvent is an alkane, and the alkane is selected from the group consisting of a pentane, a hexane, a heptane, an octane, a decane, a dodecane, and combinations thereof. In some embodiments, the alkane includes substituents. In some embodiments, the substituents include one or more halogens, such as F, Cl, Br, or I.

In some embodiments, a concentration of the first solvent ranges from about 0.01 wt. % to about 70 wt. % based on a total weight of the resist composition. In some embodiments, the concentration of the first solvent ranges from about 1 wt. % to about 50 wt. % based on a total weight of the resist composition. In some embodiments, the concentration of the first solvent ranges from about 2 wt. % to about 40 wt. % based on a total weight of the resist composition.

In some embodiments, the solvent is a third solvent different from the first solvent and the second solvent. In some embodiments, the third solvent is a C4-C14 tertiary alcohol. In some embodiments, the third solvent is not mixed with the first solvent. In some embodiments, a boiling point of the third solvent ranges from greater than 25° C. to less than 300° C. In some embodiments, the third solvent has a melting point of less than 23° C.

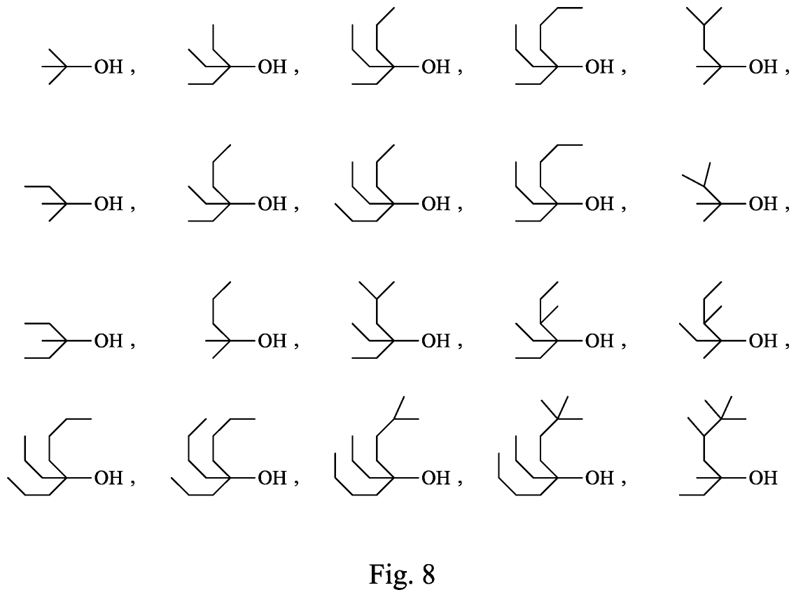

In some embodiments, the third solvent has a formula:

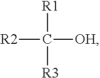

where R1, R2, and R3 are each independently a branched or unbranched, substituted or unsubstituted, C1-C11 alkyl group. In some embodiments, the substituents include one or more halogens, such as F, Cl, Br, or I. In addition to halogens, the substituents can include one or more of —OH, —COOH, —COOR, —CO, —NH₂, —NHR, —NR₂—CONH₂, —CONHR, or —CONR₂, where R is a C1-C9 alkyl group. FIG. 8 illustrates some examples of the third solvent according to embodiments of the disclosure.

In some embodiments where the third solvent is used in the resist composition, the solvent includes a fourth solvent. In some embodiments, the fourth solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, 2-heptanone, and combinations thereof.

In some embodiments, a concentration of the third solvent ranges from 3 wt. % to 100 wt. % based on a total weight of the solvent (e.g.—the total weight of the third solvent and the fourth solvent). In some embodiments, the concentration of the third solvent ranges from about 6 wt. % to about 80 wt. % based on a total weight of the resist composition. In some embodiments, the concentration of the third solvent ranges from about 10 wt. % to about 60 wt. % based on a total weight of the resist composition.

At concentrations of the resist solvent outside the disclosed ranges, resist performance and photolithographic efficiency may be reduced, leading to increased line width roughness and line edge roughness.

In some embodiments, the photoresist layer 15 is formed to a thickness of about 5 nm to about 300 nm, and to a thickness of about 10 nm to about 100 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layers. In some embodiments, each photoresist layer thickness is relatively uniform to facilitate processing. In some embodiments, the variation in thickness of the deposited photoresist layer varies by no more than ±25% from the average thickness, in other embodiments each photoresist layer thickness varies by no more than ± 10% from the average photoresist layer thickness. In some embodiments, such as high uniformity depositions on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

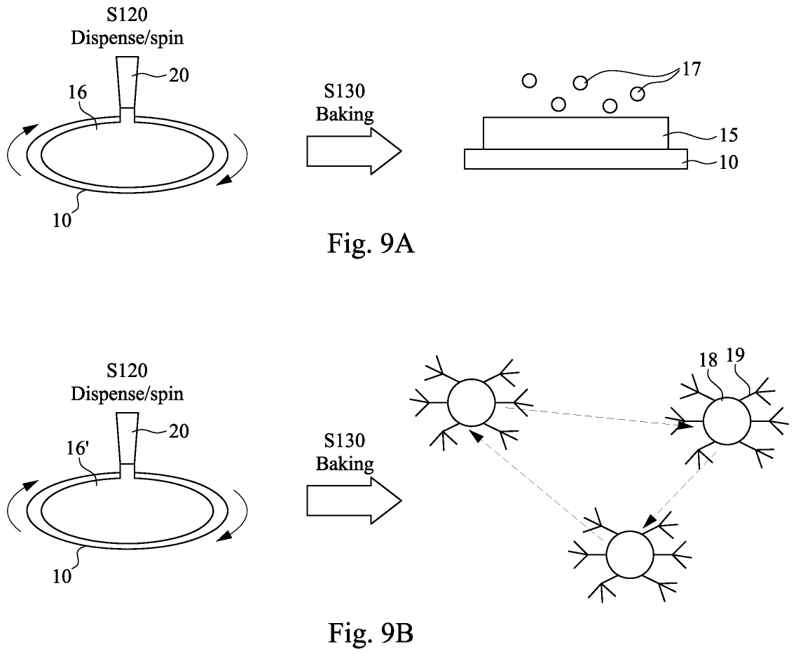

FIGS. 9A and 9B show examples of resist dispensing and baking according to embodiments of the disclosure. In FIG. 9A, a resist composition 16 including the first solvent and the second solvent is dispensed from a dispenser 20 onto a substrate 10 in operation S120 (see FIG. 1) to form resist layer 15. In some embodiments, the resist composition 16 is spin coated on the substrate 10. After the resist composition 16 is dispensed, the photoresist layer 15 is pre-exposure baked in operation S130, as disclosed herein in reference to FIG. 1. Because the first solvent has a high vapor pressure (>0.75 kPa) the first solvent 17 is readily evaporated from the photoresist layer during the pre-exposure baking operation S130, thereby reducing defects in the photolithographic operation. In some embodiments, contaminants that cause defects are dissolved into the high vapor pressure solvent. During the pre-exposure baking operation, the contaminant is vaporized along with the solvent and removed from resist composition in some embodiments.

In FIG. 9B, a resist composition 16′ including the third solvent is dispensed from a dispenser 20 onto a substrate 10 in operation S120 (see FIG. 1) to form resist layer 15. In some embodiments, the resist composition 16′ is spin coated on the substrate 10. After the resist composition 16 is dispensed, the photoresist layer 15 is pre-exposure baked in operation S130, as disclosed herein in reference to FIG. 1. The tertiary alcohol 19 of the third solvent lowers an interaction between metal cores 18 of the metal-containing resist composition. By reducing the interaction between metal cores 18, the use of the tertiary alcohol 19 containing solvent improves pattern resolution of the photoresist layer. In some embodiments the use of the tertiary alcohol 19 containing solvent reduces defects. In some embodiments, the tertiary alcohol 19 dissolves contaminants with polar functional groups, such as —OH, —COOH, —NH—, etc., that cause defects.

After preparing the photoresist composition, the photoresist composition is applied onto the layer to be patterned, as shown in FIG. 2, such as the substrate 10 to form a photoresist layer 15. In some embodiments, the photoresist is applied using a process such as a spin-on coating process, a dip coating method, an air-knife coating method, a curtain coating method, a wire-bar coating method, a gravure coating method, a lamination method, an extrusion coating method, combinations of these, or the like.

After the photoresist layer 15 has been applied to the substrate 10, a pre-exposure bake of the photoresist layer 15 is performed in some embodiments to cure or dry the photoresist prior to radiation exposure (see FIG. 1, operation S120). The curing and drying of the photoresist layer removes the solvent component while leaving behind organometallic compound, and any additives.

FIGS. 3A and 3B illustrate selective exposure or patternwise exposure of the photoresist layer to form an exposed region 50 and an unexposed region 52. In some embodiments, the exposure to radiation is carried out by placing the photoresist-coated substrate in a photolithography tool. The photolithography tool includes a photomask 30/65, optics, an exposure radiation source to provide the radiation 45/97 for exposure, and a movable stage for supporting and moving the substrate under the exposure radiation.

In some embodiments, the radiation source (not shown) supplies radiation 45/97, such as ultraviolet light, to the photoresist layer 15 to induce a reaction of the photoresist components in those regions of the photoresist layer to which the radiation 45/97 impinges. In some embodiments, the radiation is electromagnetic radiation, such as g-line (wavelength of about 436 nm), i-line (wavelength of about 365 nm), ultraviolet radiation, far ultraviolet radiation, extreme ultraviolet, electron beam, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F2 excimer laser light (wavelength of 157 nm), or a CO₂ laser-excited Sn plasma (extreme ultraviolet, wavelength of 13.5 nm). In some embodiments, the patterned radiation 45/97 is extreme ultraviolet light having a 13.5 nm wavelength.

In some embodiments, optics (not shown) are used in the photolithography tool to expand, reflect, or otherwise control the radiation before or after the radiation 45/97 is patterned by the photomask 30/65. In some embodiments, the optics include one or more lenses, mirrors, filters, and combinations thereof to control the radiation 45/97 along its path.

In some embodiments, the exposure of the photoresist layer 15 uses an immersion lithography technique. In such a technique, an immersion medium (not shown) is placed between the final optics and the photoresist layer, and the exposure radiation 45 passes through the immersion medium.

After the photoresist layer 15 has been exposed to the exposure radiation 45/97, a post-exposure baking is performed in some embodiments to assist in the generating, dispersing, and reacting of organometallic compounds with ions or free radicals generated from the impingement of the radiation 45/97 upon the photoresist layer during the exposure (see FIG. 1, operation S140). Such thermal assistance helps to create or enhance chemical reactions that generate chemical differences between the exposed region 50 and the unexposed region 52 within the photoresist layer 15. These chemical differences also cause differences in the solubility between the exposed region 50 and the unexposed region 52. In some embodiments, the post-exposure baking S150 occurs under conditions disclosed herein in reference to FIG. 1

In some embodiments, the exposure to actinic radiation (S140) and subsequent post exposure baking (S150) (see FIG. 1) cause crosslinking of the organometallic compounds, thereby making the exposed portions of the photoresist less soluble in organic solvent negative resist developers.

After the post exposure baking operation S150, the selectively or patternwise exposed photoresist layer is developed in operation S160 (see FIG. 1). In some embodiments of the disclosure, the developer composition 57, includes: a solvent and an acid or a base. In some embodiments, the developer includes from about 100 ppm to about 100 wt. % based on the total weight of the mixture of the first and second solvents disclosed herein with reference to the resist composition solvents. In other embodiments, the developer composition 57 includes from about 100 ppm to about 100 wt. % based on the total weight of the tertiary alcohol third solvent disclosed herein with reference to the resist composition solvents.

In some embodiments, the developer includes one or more of a solvent having Hansen solubility parameters of 18>δ_{d}>3, 7>δₚ>1, and 7>δₕ>1; an organic acid having an acid dissociation constant, pKa, of −11<pKa<4; and a Lewis acid, wherein the organic acid and the Lewis acid are different. In some embodiments, the developer includes a base having a pKₐ of 40>pKₐ>9.5.

The units of the Hansen solubility parameters are (Joules/cm³)^{1/2} or, equivalently, MPa^{1/2} and are based on the idea that one molecule is defined as being like another if it bonds to itself in a similar way. δ_{d} is the energy from dispersion forces between molecules. δₚ is the energy from dipolar intermolecular force between the molecules. δₕ is the energy from hydrogen bonds between molecules. The three parameters, δ_{d}, δₚ, and δₕ, can be considered as coordinates for a point in three dimensions, known as the Hansen space. The nearer two molecules are in Hansen space, the more likely they are to dissolve into each other.

In some embodiments, the concentration of the solvent having Hansen solubility parameters of 18>δ_{d}>3, 7>δₚ>1, and 7>δₕ>1 ranges from about 60 wt. % to about 99 wt. % based on a total weight of the developer composition. In some embodiments, the concentration of the solvent is greater than 60 wt. %. In other embodiments, the concentration of the concentration of the solvent ranges from about 70 wt. % to about 90 wt. % based on a total weight of the developer composition. In some embodiments, the solvent is one or more of n-butyl acetate, methyl n-amyl ketone, hexane, heptane, and amyl acetate.

In some embodiments, the organic acid is one or more of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, and maleic acid. In some embodiments, the concentration of the organic acid is about 0.001 wt. % to about 30 wt. % based on a total weight of the developer composition.

In some embodiments, suitable bases for the photoresist developer composition 57 include an alkanolamine, a triazole, or an ammonium compound. In some embodiments, suitable bases include an organic base selected from the group consisting of monoethanolamine, monoisopropanolamine, 2-amino-2-methyl-1-propanol, 1H-benzotriazole, 1,2,4-triazole, 1,8-diazabicycloundec-7-ene, tetramethylammonium hydroxide, tetraethylammonium hydroxide, tetrapropylammonium hydroxide, and tetrabutylammonium hydroxide, and combinations thereof; or inorganic bases selected from the group consisting of ammonium hydroxide, ammonium sulfamate, ammonium carbamate, and combinations thereof. In some embodiments, the base is selected from the group consisting of monoisopropanolamine, 2-amino-2-methyl-1-propanol, 1H-benzotriazole, 1,2,4-triazole, 1,8-diazabicycloundec-7-ene, and combinations thereof. In some embodiments, the concentration of the base is about 0.001 wt. % to about 30 wt. % based on a total weight of the developer composition.

In some embodiments, the concentration of the Lewis acid is about 0.1 wt. % to about 15 wt. % based on a total weight of the developer composition 57, and in other embodiments, the concentration of the Lewis acid is about 1 wt. % to about 5 wt. % based on a total weight of the developer composition.

In some embodiments, the developer composition 57 includes another solvent having Hansen solubility parameters of 25>δ_{d}>13, 25>δₚ>3, and 30>δₕ>4 that is different from the solvent having Hansen solubility parameters of 18>δ_{d}>3, 7>δₚ>1, and 7>δₕ>1. In some embodiments, the concentration of the another solvent ranges from about 0.1 wt. % to less than about 40 wt. % based on a total weight of the developer composition. In some embodiments, the another solvent is one or more of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, or acetic acid.

In some embodiments, the developer composition 57 includes about 0.001 wt. % to about 30 wt. % of a chelate based on the total weight of the developer composition. In other embodiments, the developer composition includes about 0.1 wt. % to about 20 wt. % of the chelate based on the total weight of the developer composition. In some embodiments, the chelate is one or more of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, ethylenediamine, or the like.

In some embodiments, the developer composition 57 includes water or ethylene glycol at a concentration of about 0.001 wt. % to about 30 wt. % based on a total weight of the developer composition.

In some embodiments, the photoresist developer 57 composition includes a surfactant in a concentration range of from about 0.001 wt. % to about less than 5 wt. % based on a total weight of the developer composition to increase the solubility and reduce the surface tension on the substrate. In other embodiments, the concentration of the surfactant ranges from about 0.01 wt. % to about 1 wt. % based on the total weight of the developer composition.

At concentrations of the developer composition components outside the disclosed ranges, developer composition performance and development efficiency may be reduced, leading to increased photoresist residue and scum in the photoresist pattern, and increased line width roughness and line edge roughness.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated in operation S160, as shown in FIG. 4. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. during the development operation. The development operation continues for between about 10 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process, the developer 57 dissolves the radiation-exposed regions 50 of a positive tone photoresist composition in some embodiments, exposing the surface of the substrate 10, as shown in FIG. 5A, and leaving behind well-defined unexposed photoresist regions 52, having improved definition than provided by conventional photoresist photolithography. In other embodiments, the developer 57 dissolves the radiation-unexposed regions 52 of a negative tone photoresist composition exposing the surface of the substrate 10, as shown in FIG. 5B, and leaving behind well-defined exposed photoresist regions 50, having improved definition than provided by conventional photoresist photolithography.

After the developing operation S160, remaining developer is removed from the patterned photoresist covered substrate. The remaining developer is removed using a spin-dry process in some embodiments, although any suitable removal technique may be used. After the photoresist layer 15 is developed, and the remaining developer is removed, additional processing is performed while the photoresist pattern 50, 52 is in place. For example, an etching operation, using dry or wet etching, is performed in some embodiments, to transfer the pattern 55a, 55b of the photoresist layer to the underlying substrate 10, forming recesses 55a′, 55b′ as shown in FIGS. 6A and 6B. The substrate 10 has a different etch resistance than the photoresist layer 15. In some embodiments, the etchant is more selective to the substrate 10 than the photoresist layer 15.

In some embodiments, the substrate 10 and the photoresist layer 15 contain at least one etching resistance molecule. In some embodiments, the etching resistant molecule includes a molecule having a low Onishi number structure, a double bond, a triple bond, silicon, silicon nitride, titanium, titanium nitride, aluminum, aluminum oxide, silicon oxynitride, combinations thereof, or the like.

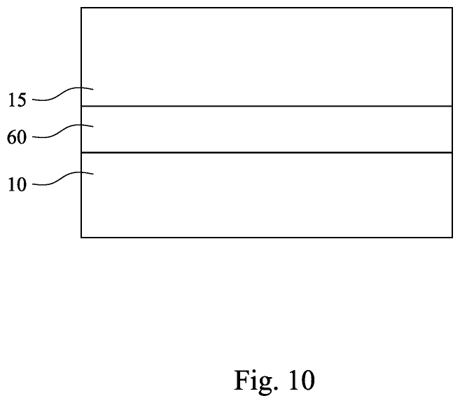

In some embodiments, a target layer 60 is disposed over the substrate prior to forming the photoresist layer, as shown in FIG. 10. In some embodiments, the target layer 60 is a metallization layer or a dielectric layer, such as a passivation layer, disposed over a metallization layer. In embodiments where the target layer 60 is a metallization layer, the target layer 60 is formed of a conductive material using metallization processes, and metal deposition techniques, including chemical vapor deposition, atomic layer deposition, and physical vapor deposition (sputtering). Likewise, if the target layer 60 is a dielectric layer, the target layer 60 is formed by dielectric layer formation techniques, including thermal oxidation, chemical vapor deposition, atomic layer deposition, and physical vapor deposition.

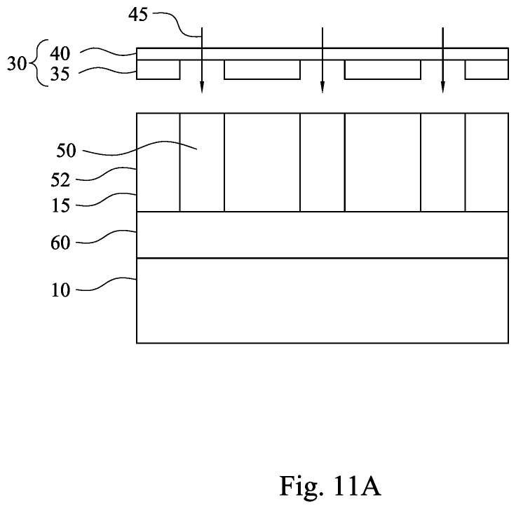

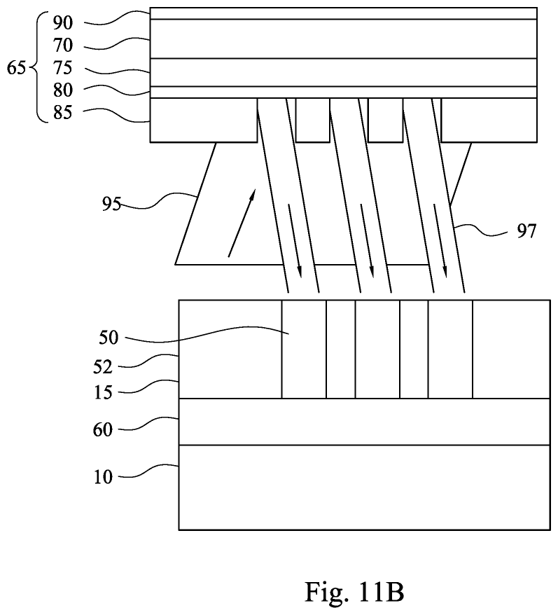

The photoresist layer 15 is subsequently selectively exposed or patternwise exposed to actinic radiation 45 to form exposed regions 50 and unexposed regions 52 in the photoresist layer, as shown in FIGS. 11A and 11B, and described herein in relation to FIGS. 3A and 3B.

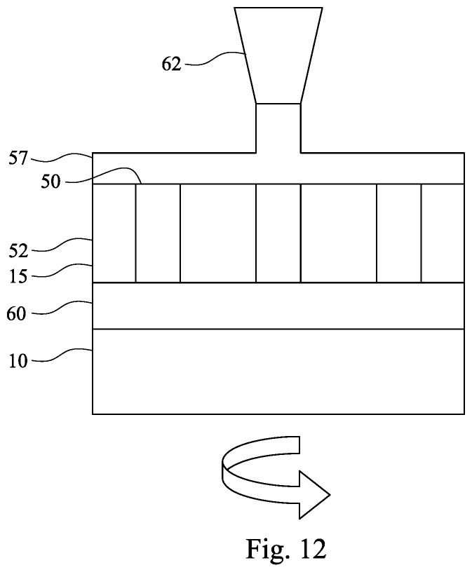

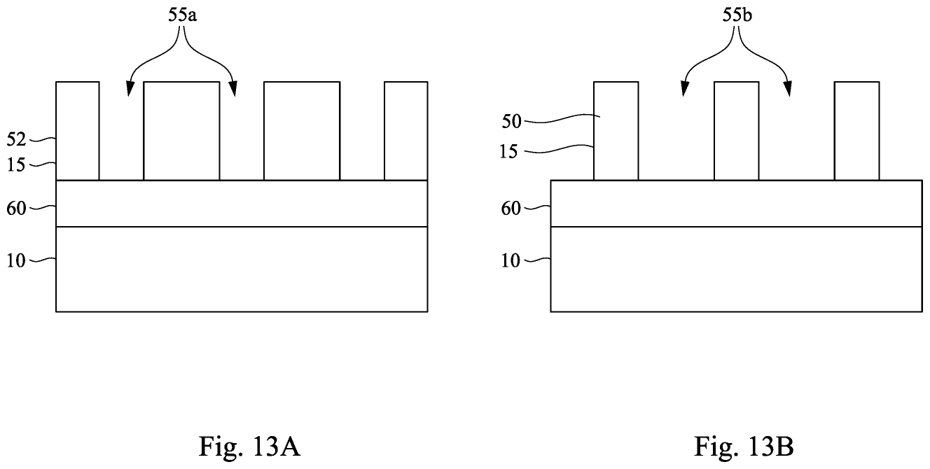

As shown in FIG. 12, the selectively exposed or patternwise exposed photoresist layer 15 is developed by dispensing developer 57 from a dispenser 62 to form a pattern of photoresist openings 55a, 55b, as shown in FIGS. 13A and 13B. FIG. 13A illustrates the development of a positive tone photoresist, and FIG. 13B illustrates the development of a negative tone photoresist. The development operation is similar to that explained with reference to FIGS. 4, 5A, and 5B, herein.

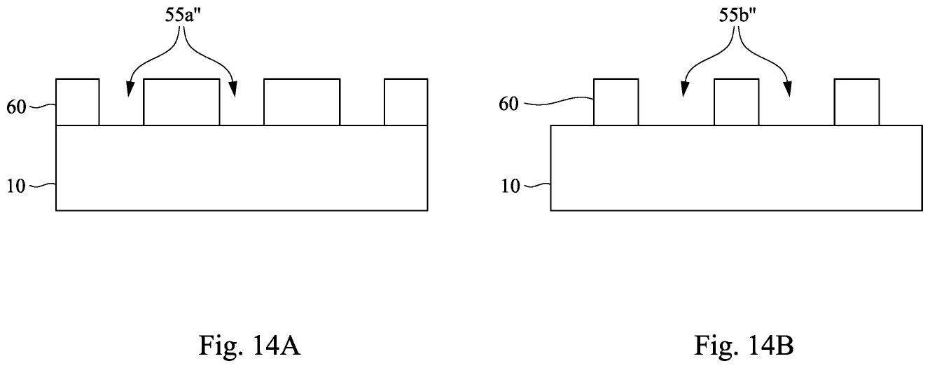

Then, as shown in FIGS. 14A and 14B, the pattern 55a, 55b in the photoresist layer 15 is transferred to the target layer 60 using an etching operation and the photoresist layer is removed, as explained with reference to FIGS. 6A and 6B to form pattern 55a″, 55b″ in the target layer 60.

Other embodiments include other operations before, during, or after the operations described above. In some embodiments, the disclosed methods include forming semiconductor devices, including fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, and combinations thereof are formed, according to embodiments of the disclosure.

The novel photoresist compositions provide improved solubility of the photoresist components in the photoresist composition. The novel photoresist compositions and methods according to the present disclosure provide higher semiconductor device feature resolution and density at higher wafer exposure throughput with reduced defects in a higher efficiency process than conventional exposure techniques. Reduced exposure dose than conventional exposure techniques are enabled by the resist compositions and photolithographic techniques according to embodiments of the disclosure. In some embodiments, an exposure dose of about 10 mj to about mj is sufficient to provide a line width roughness of less than 5.0 nm. The novel photoresist solvents of the present disclosure reduce the defects by greater than 5% compared to the use of conventional photoresist solvents in some embodiments.

An embodiment of the disclosure is a method for manufacturing a semiconductor device, including forming a resist layer including a resist composition over a substrate. The resist composition includes: a metal, a ligand, and a solvent. The solvent is mixture of a first solvent having a vapor pressure of at least 0.75 kPa, wherein the first solvent is one or more of an ether, an ester, an alkane, an aldehyde, or a ketone, and a second solvent different from the first solvent. Alternatively, the solvent is a third solvent, wherein the third solvent is a C4-C14 tertiary alcohol. The resist layer is patterned. In an embodiment, the method includes heating the resist layer at a temperature ranging from 40° C. to 300° C. before patterning the resist layer. In an embodiment, the first solvent is a C2-C14 compound. In an embodiment, the solvent includes the first solvent, and the first solvent includes an ester, and the ester is selected from the group consisting of a methyl acetate, an ethyl acetate, a propyl acetate, an isopropyl acetate, an n-butyl acetate, an isobutyl acetate, a sec-butyl acetate, a tert-butyl acetate, and combinations thereof. In an embodiment, the solvent includes the first solvent, and the first solvent is an ether, and the ether is selected from the group consisting of a diethyl ether, a dipropyl ether, an ethyl propyl ether, a butyl propyl ether, a tert-amyl methyl ether, and combinations thereof. In an embodiment, the solvent includes the first solvent, and the first solvent is a ketone or an aldehyde, the ketone is selected from the group consisting of a dimethyl ketone, a methyl ethyl ketone, a diethyl ketone, a methyl propyl ketone, an ethyl propyl ketone, and combinations thereof, and the aldehyde is selected from the group consisting of a propanal, a butanal, a pentanal, a hexanal, a 3-methylbutanal, a 2-methylbutanal, a 2-methylpentanal, a 2 ethylpentanal, and combinations thereof. In an embodiment, the solvent includes the first solvent, and the first solvent is an alkane, and the alkane is selected from the group consisting of a pentane, a hexane, a heptane, an octane, a decane, a dodecane, and combinations thereof. In an embodiment, the solvent includes the second solvent, and the second solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone. In an embodiment, a concentration of the first solvent ranges from 0.01 wt. % to 70 wt. % based on a total weight of the resist composition. In an embodiment, the solvent includes the third solvent, and the third solvent is:

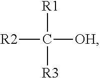

where R1, R2, and R3 are each independently a branched or unbranched, substituted or unsubstituted, C1-C11 alkyl group.

Another embodiment of the disclosure is a method for manufacturing a semiconductor device, including forming a photoresist layer including a photoresist composition over a substrate. The photoresist composition includes an organometallic compound, and a solvent. The solvent is mixture of a first solvent having a boiling point ranging from greater than 25° C. to less than 300° C., and a melting point less than 23° C., wherein the first solvent is one or more of an ether, an ester, an alkane, an aldehyde, or a ketone, and a second solvent different from the first solvent. Alternatively, the solvent is a third solvent, wherein the third solvent is a C4-C14 tertiary alcohol. The photoresist layer is selectively exposed to actinic radiation to form a latent image in the photoresist layer. The selectively exposed photoresist layer is developed to form a pattern in the photoresist layer. In an embodiment, the method includes heating the photoresist layer at a temperature ranging from 40° C. to 300° C. before the selectively exposing the photoresist layer. In an embodiment, the method includes heating the selectively exposed photoresist layer at a temperature ranging from 80° C. to 250° C. before the developing the selectively exposed photoresist layer. In an embodiment, the third solvent has a boiling point ranging from greater than 25° C. to less than 300° C., and a melting point less than 23° C. In an embodiment, the solvent includes the third solvent and a fourth solvent, and the fourth solvent is one or more selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone. In an embodiment, a concentration of the third solvent ranges from 3 wt. % to 100 wt. % based on a total weight of the solvent.

Another embodiment of the disclosure is a composition, including: a metal; a ligand; and a solvent. The solvent is mixture of a first solvent having a vapor pressure of at least 0.75 kPa, wherein the first solvent is one or more of an ether, an ester, an alkane, an aldehyde, or a ketone, and a second solvent different from the first solvent, or the solvent is a third solvent, wherein the third solvent is a C4-C14 tertiary alcohol. In an embodiment, the solvent includes the first solvent, and the first solvent is a C2-C14 compound. In an embodiment, the solvent includes the third solvent, and the third solvent is:

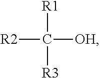

where R1, R2, and R3 are each independently a branched or unbranched, substituted or unsubstituted, C1-C11 alkyl group. In an embodiment, a concentration of the first solvent ranges from 0.01 wt. % to 70 wt. % based on a total weight of the composition. In an embodiment, the solvent includes the first solvent, and the first solvent includes an ester, and the ester is selected from the group consisting of a methyl acetate, an ethyl acetate, a propyl acetate, an isopropyl acetate, an n-butyl acetate, an isobutyl acetate, a sec-butyl acetate, a tert-butyl acetate, and combinations thereof. In an embodiment, the solvent includes the first solvent, and the first solvent is an ether, and the ether is selected from the group consisting of a diethyl ether, a dipropyl ether, an ethyl propyl ether, a butyl propyl ether, a tert-amyl methyl ether, and combinations thereof. In an embodiment, the solvent includes the first solvent, and the first solvent is a ketone or an aldehyde, and the ketone is selected from the group consisting of a dimethyl ketone, a methyl ethyl ketone, a diethyl ketone, a methyl propyl ketone, an ethyl propyl ketone, and combinations thereof, and the aldehyde is selected from the group consisting of a propanal, a butanal, a pentanal, a hexanal, a 3-methylbutanal, a 2-methylbutanal, a 2-methylpentanal, a 2 ethylpentanal, and combinations thereof. In an embodiment, the first solvent is an alkane, and the alkane is selected from the group consisting of a pentane, a hexane, a heptane, an octane, a decane, a dodecane, and combinations thereof. In an embodiment, the solvent includes the second solvent, and the second solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, 2-heptanone, and combinations thereof.

Another embodiment of the disclosure is a method for manufacturing a semiconductor device, including applying a metallic photoresist composition over a target layer disposed over a substrate to form a photoresist layer. The metallic photoresist composition includes a solvent. The solvent is a mixture of a first solvent and a second solvent, wherein the first solvent is one or more selected from the group consisting of an ether, an ester, an alkane, an aldehyde, and a ketone. The first solvent has a vapor pressure of at least 0.75 kPa, and the second solvent is different from the first solvent. Alternatively, the solvent is a third solvent, wherein the third solvent is a tertiary alcohol having a boiling point ranging from greater than 25° C. to less than 300° C., and a melting point less than 23° C. The photoresist layer is patternwise exposed to actinic radiation. A developer composition is applied to the patternwise exposed photoresist layer to form a pattern in the photoresist layer. In an embodiment, the solvent includes the first solvent, and the first solvent is a C2-C14 compound. In an embodiment, the solvent includes the first solvent, and the first solvent is selected from the group consisting of a methyl acetate, an ethyl acetate, a propyl acetate, an isopropyl acetate, an n-butyl acetate, an isobutyl acetate, a sec-butyl acetate, a tert-butyl acetate, a diethyl ether, a dipropyl ether, an ethyl propyl ether, a butyl propyl ether, a tert-amyl methyl ether, a dimethyl ketone, a methyl ethyl ketone, a diethyl ketone, a methyl propyl ketone, an ethyl propyl ketone, a propanal, a butanal, a pentanal, a hexanal, a 3-methylbutanal, a 2-methylbutanal, a 2-methylpentanal, a 2 ethylpentanal, a pentane, a hexane, a heptane, an octane, a decane, a dodecane, and combinations thereof. In an embodiment, the solvent includes the third solvent, and the third solvent has a formula:

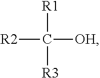

where R1, R2, and R3 are each independently a branched or unbranched, substituted or unsubstituted, C1-C11 alkyl group. In an embodiment, the metallic photoresist composition includes an organometallic having a formula MₐR_{b}X_{c}, where M is at least one of Sn, Bi, Sb, In, Te, Ti, Zr, Hf, V, Co, Mo, W, Al, Ga, Si, Ge, P, As, Y, La, Ce, or Lu; R is a substituted or unsubstituted C3-C6 alkyl group, C3-C6 alkenyl group, or C3-C6 carboxylate group; X is an amino group, an alkoxy group, a carboxylate group, a halogen, or a sulfonate; and 1≤a≤2, b≥1, c≥1, and b+c≤5.

Another embodiment of the disclosure is a photoresist composition, including an organometallic compound and a solvent. The solvent is mixture of a first solvent having a boiling point ranging from greater than 25° C. to less than 300° C., and a melting point less than 23° C., wherein the first solvent is one or more of an ether, an ester, an alkane, an aldehyde, or a ketone, and a second solvent different from the first solvent, or the solvent is a third solvent, wherein the third solvent is a C4-C15 tertiary alcohol. In an embodiment, the solvent includes the first solvent, and the first solvent is a C2-C14 compound. In an embodiment, the solvent includes the first solvent, and the first solvent is selected from the group consisting of a methyl acetate, an ethyl acetate, a propyl acetate, an isopropyl acetate, an n-butyl acetate, an isobutyl acetate, a sec-butyl acetate, a tert-butyl acetate, a diethyl ether, a dipropyl ether, an ethyl propyl ether, a butyl propyl ether, a tert-amyl methyl ether, a dimethyl ketone, a methyl ethyl ketone, a diethyl ketone, a methyl propyl ketone, an ethyl propyl ketone, a propanal, a butanal, a pentanal, a hexanal, a 3-methylbutanal, a 2-methylbutanal, a 2-methylpentanal, a 2 ethylpentanal, a pentane, a hexane, a heptane, an octane, a decane, a dodecane, and combinations thereof. In an embodiment, the solvent includes the third solvent, and the third solvent has a formula:

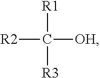

where R1, R2, and R3 are each independently a branched or unbranched, substituted or unsubstituted, C1-C11 alkyl group. In an embodiment, the photoresist composition includes a fourth solvent selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, 2-heptanone, and combinations thereof.

Another embodiment of the disclosure is a photoresist composition, including an organometallic and a solvent. The solvent includes a mixture of a first solvent and a second solvent. The first solvent is one or more selected from the group consisting of an ether, an ester, an alkane, an aldehyde, and a ketone. The first solvent has a vapor pressure of at least 0.75 kPa, and the second solvent is different from the first solvent. Alternatively, the solvent includes a third solvent, wherein the third solvent is a tertiary alcohol having a boiling point ranging from greater than 25° C. to less than 300° C., and a melting point less than 23° C. In an embodiment, the organometallic has a formula MₐR_{b}X_{c}, where M is at least one of Sn, Bi, Sb, In, Te, Ti, Zr, Hf, V, Co, Mo, W, Al, Ga, Si, Ge, P, As, Y, La, Ce, or Lu; R is a substituted or unsubstituted C3-C6 alkyl group, C3-C6 alkenyl group, or C3-C6 carboxylate group; X is an amino group, an alkoxy group, a carboxylate group, a halogen, or a sulfonate; and 1≤a≤2, b≥1, c≥1, and b+c≤5. In an embodiment, the solvent includes the first solvent and the second solvent, wherein the first solvent is selected from the group consisting of a methyl acetate, an ethyl acetate, a propyl acetate, an isopropyl acetate, an n-butyl acetate, an isobutyl acetate, a sec-butyl acetate, a tert-butyl acetate, a diethyl ether, a dipropyl ether, an ethyl propyl ether, a butyl propyl ether, a tert-amyl methyl ether, a dimethyl ketone, a methyl ethyl ketone, a diethyl ketone, a methyl propyl ketone, an ethyl propyl ketone, a propanal, a butanal, a pentanal, a hexanal, a 3-methylbutanal, a 2-methylbutanal, a 2-methylpentanal, a 2 ethylpentanal, a pentane, a hexane, a heptane, an octane, a decane, a dodecane, and combinations thereof; and the second solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone. In an embodiment, the solvent includes the third solvent, and the third solvent has a formula:

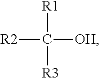

where R1, R2, and R3 are each independently a branched or unbranched, substituted or unsubstituted, C1-C11 alkyl group. In an embodiment, the photoresist composition includes a fourth solvent selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, 2-heptanone, and combinations thereof.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A composition, comprising:
a metal;
a ligand; and
a solvent,
wherein the solvent is mixture of a first solvent selected from the group consisting of a methyl acetate, a propyl acetate, an isopropyl acetate, a diethyl ether, a dipropyl ether, an ethyl propyl ether, a butyl propyl ether, a tert-amyl methyl ether, a dimethyl ketone, a methyl ethyl ketone, a diethyl ketone, a methyl propyl ketone, an ethyl propyl ketone, a propanal, a butanal, a pentanal, a hexanal, a 3-methylbutanal, a 2-methylbutanal, a 2-methylpentanal, a 2-ethylpentanal, a pentane, a heptane, an octane, a decane, a dodecane, and combinations thereof, and a second solvent different from the first solvent, or
the solvent is a third solvent, wherein the third solvent is a tertiary alcohol selected from the group consisting of

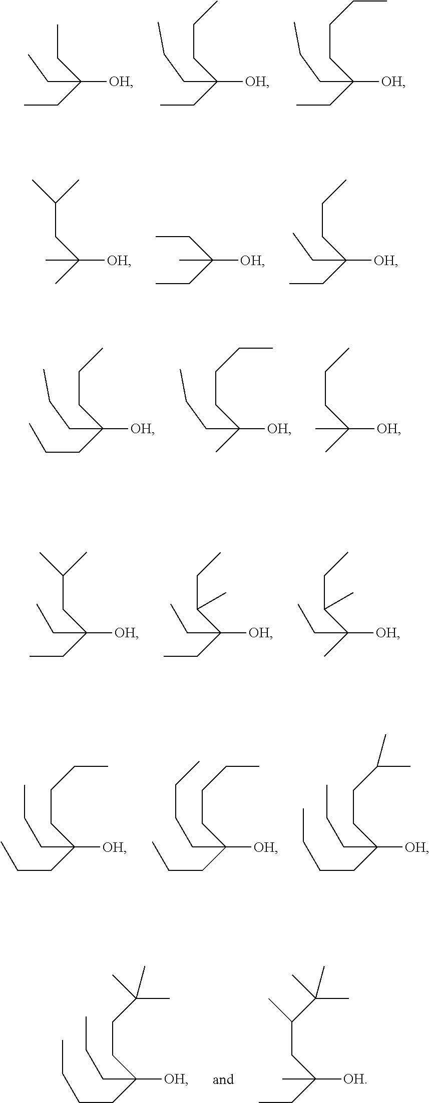

2. The composition of claim 1, wherein the composition includes the first solvent and the first solvent has a vapor pressure of at least 0.75 kPa.

3. The composition of claim 1, wherein the solvent includes the first solvent and a concentration of the first solvent ranges from 0.01 wt. % to 70 wt. % based on a total weight of the composition.

4. The composition of claim 1, wherein the solvent includes the first solvent and the second solvent, and the second solvent is selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone.

5. The composition of claim 1, wherein the composition includes the third solvent and the third solvent has a boiling point ranging from greater than 25° C. to less than 300° C., and a melting point less than 23° C.

6. The composition of claim 1, wherein the composition includes the third solvent, and the composition further comprises a fourth solvent different from the third solvent.

7. The composition of claim 6, wherein the fourth solvent is one or more selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone.

8. The composition of claim 7, wherein the solvent includes the third solvent, and a concentration of the third solvent ranges from 3 wt. % to 100 wt. % based on a total weight of the solvent.

9. The composition of claim 1, wherein the metal is at least one of Sn, Bi, Sb, In, Te, Ti, Zr, Hf, V, Co, Mo, W, Al, Ga, Si, Ge, P, As, Y, La, Ce, or Lu.

10. A photoresist composition, comprising:
an organometallic compound, and
a solvent,
wherein the solvent is mixture of one or more first solvents having a boiling point ranging from greater than 25° C. to less than 300° C., and a melting point less than 23° C. selected from the group consisting of a methyl acetate, a propyl acetate, an isopropyl acetate, a diethyl ether, a dipropyl ether, an ethyl propyl ether, a butyl propyl ether, a tert-amyl methyl ether, a dimethyl ketone, a methyl ethyl ketone, a diethyl ketone, a methyl propyl ketone, an ethyl propyl ketone, a propanal, a butanal, a pentanal, a hexanal, a 3-methylbutanal, a 2-methylbutanal, a 2-methylpentanal, a 2-ethylpentanal, a pentane, a heptane, an octane, a decane, a dodecane, and combinations thereof, and a second solvent different from the first solvent, or
the solvent is a third solvent, wherein the third solvent includes one or more tertiary alcohols selected from the group consisting of

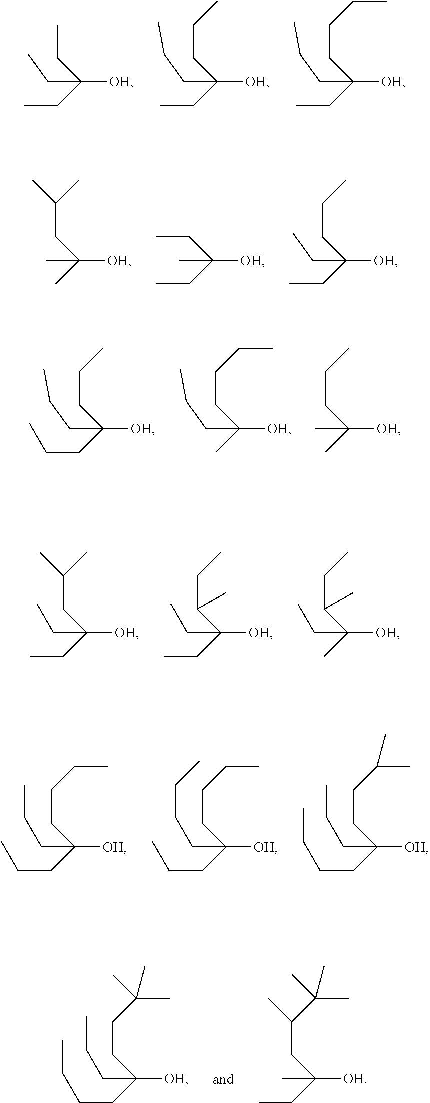

11. The photoresist composition of claim 10, wherein the organometallic compound has a formula MₐR_{b}X_{c}, where M is at least one of Sn, Bi, Sb, In, Te, Ti, Zr, Hf, V, Co, Mo, W, Al, Ga, Si, Ge, P, As, Y, La, Ce, or Lu; R is a substituted or unsubstituted C3-C6 alkyl group, C3-C6 alkenyl group, or C3-C6 carboxylate group; X is an amino group, an alkoxy group, a carboxylate group, a halogen, or a sulfonate; and 1≤a≤2, b≥1, c≥1, and b+c≤5.

12. The photoresist composition of claim 10, wherein photoresist composition includes the third solvent and the third solvent has a boiling point ranging from greater than 25° C. to less than 300° C. and a melting point less than 23° C.

13. The photoresist composition of claim 10, wherein the solvent includes the third solvent and a fourth solvent, and the fourth solvent is one or more selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone.

14. The photoresist composition of claim 13, wherein a concentration of the third solvent ranges from 3 wt. % to 100 wt. % based on a total weight of the solvent.

15. The photoresist composition of claim 10, wherein the solvent includes the first solvent and a concentration of the first solvent ranges from 0.01 wt. % to 70 wt. % based on a total weight of the composition.

16. A photoresist composition, comprising:
an organometallic compound having a formula MₐR_{b}X_{c}, where M is at least one of Sn, Bi, Sb, In, Te, Ti, Zr, Hf, V, Co, Mo, W, Al, Ga, Si, Ge, P, As, Y, La, Ce, or Lu; R is a substituted or unsubstituted C3-C6 alkyl group, C3-C6 alkenyl group, or C3-C6 carboxylate group; X is an amino group, an alkoxy group, a carboxylate group, a halogen, or a sulfonate; and 1≤a≤2, b≥1, c≥1, and b+c≤5; and
a solvent,
wherein the solvent is mixture of one or more first solvents having a boiling point ranging from greater than 25° C. to less than 300° C., and a melting point less than 23° C., and a second solvent different from the first solvent selected from the group consisting of selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone, or
the solvent is a third solvent, wherein the third solvent includes one or more tertiary alcohols selected from the group consisting of

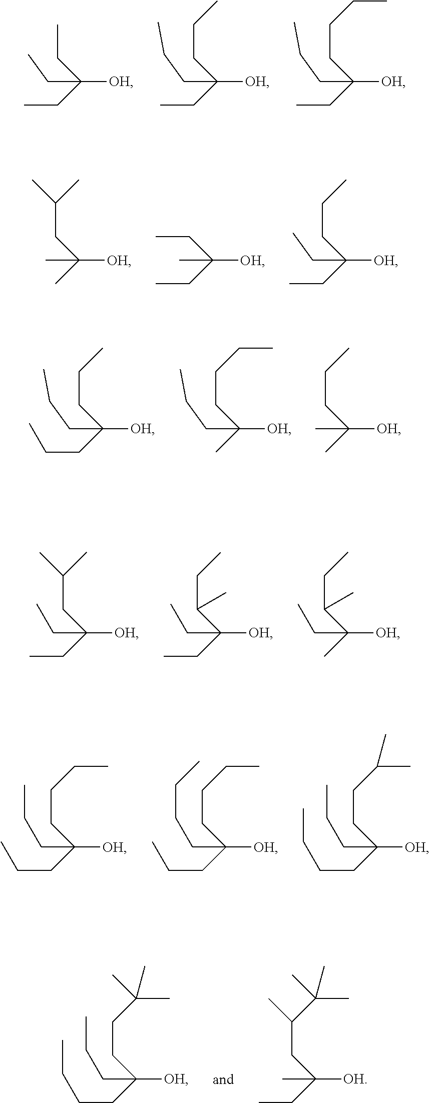

17. The photoresist composition of claim 16, wherein photoresist composition includes the third solvent and the third solvent has a boiling point ranging from greater than 25° C. to less than 300° C. and a melting point less than 23° C.

18. The photoresist composition of claim 16, wherein the solvent includes the third solvent and a fourth solvent, and the fourth solvent is one or more selected from the group consisting of propylene glycol methyl ether acetate, propylene glycol monomethyl ether, 1-ethoxy-2-propanol, γ-butyrolactone, cyclohexanone, ethyl lactate, methanol, ethanol, propanol, isopropanol, n-butanol, acetone, dimethylformamide, tetrahydrofuran, methyl isobutyl carbinol, n-butyl acetate, and 2-heptanone.

19. The photoresist composition of claim 18, wherein a concentration of the third solvent ranges from 3 wt. % to 100 wt. % based on a total weight of the solvent.

20. The photoresist composition of claim 16, wherein M is selected from the group consisting of Sn, Bi, Sb, In, Te, and combinations thereof.
